(19) United States
(12) Patent Application Publication
(10) Pub. No.: US 2014/0252322 A1
(43) Pub. Date: Sep. 11, 2014

(54) DISPLAY DEVICE INTEGRATED WITH TOUCH SCREEN PANEL

(71) Applicant: Samsung Display Co., Ltd., Yongin-City (KR)

(72) Inventors: Hwa-Jeong Kim, Yongin-City (KR); Chi-Wook An, Yongin-City (KR)

(73) Assignee: Samsung Display Co., Ltd., Yongin-City (KR)

(21) Appl. No.: 13/933,029

(22) Filed: Jul. 1, 2013

(30) Foreign Application Priority Data
Mar. 8, 2013 (KR) 10-2013-0024761

(51) Int. Cl. H01L 27/32

(52) U.S. Cl. CPC H01L 27/323
USPC 257/40

(57) ABSTRACT

A display device integrated with a touch screen panel in an embodiment of the present invention includes: a first substrate, a second substrate on the first substrate, a plurality of touch sensing cells in an active region between the first substrate and the second substrate, and a plurality of pixels on an active area of the second substrate.

### CROSS-REFERENCE TO RELATED APPLICATION

This application claims priority to and the benefit of Korean Patent Application No. 10-2013-0024761, filed on Mar. 8, 2013, in the Korean Intellectual Property Office, the entire content of which is incorporated herein by reference in its entirety.

### BACKGROUND

1. Field

An aspect of the present invention relates to a display device integrated with a touch screen panel.

2. Description of the Related Art

A touch screen panel is an input device capable of inputting a user's instruction by selecting instruction contents displayed on a screen, such as a display device, or the like, with a human hand or an object.

The touch screen panel is provided to a front face of the display device to convert a contact position directly contacted by the human hand or the object into an electrical signal. Therefore, the instruction contents selected at the contact position are recognized as input signals.

Since the touch screen panel as described above may substitute a separate input device such as a keyboard or a mouse which is connected to the display device and operated, applications thereof have been gradually extended.

### SUMMARY

Aspects of embodiments of the present invention are directed toward a display device integrated with a touch screen panel capable of providing improved flexibility while implementing in a thin shape by simplifying a structure thereof.

According to an embodiment of the present invention, a display device integrated with a touch screen panel includes: a first substrate, a second substrate on the first substrate, a plurality of touch sensing cells formed in an active region between the first substrate and the second substrate, and a plurality of pixels formed on an active area of the second substrate.

The first and second substrates may include a flexible thin film substrate.

The first and second substrates may include a transparent substrate.

The touch sensing cells may include a transparent electrode material.

The pixels may display an image by emitting light in a direction towards where the touch sensing cells are formed.

The pixels may include pixels of an organic light emitting display device having an organic light emitting diode.

A sealing substrate on the pixels may be further included.

The sealing substrate may include a thin film substrate.

The display device integrated with a touch screen panel may further include outside wiring lines in a non active region between the first and second substrates.

The outside wiring lines may include an opaque metal.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a plan view showing an example of a touch screen panel.

FIG. 2 is a cross-sectional view showing a display device integrated with a touch screen panel according to an embodiment of the present invention.

FIG. 3 is a cross-sectional view showing an example of a pixel shown in FIG. 2.

### DETAILED DESCRIPTION

Hereinafter, example embodiments of the present invention will be described in more detail with reference to the accompanying drawings. However, the present invention is not limited to the example embodiments disclosed below, and may be implemented in various different forms. In addition, in the following description, when there is a case in which any part is described as connected to another part, it includes a case in which the parts are directly connected with each other and a case in which the parts are connected with each other, having another element interposed therebetween. In addition, in order to describe in more detail of the embodiments of the present invention, a part having no direct relationship with the embodiments is omitted from the drawings.

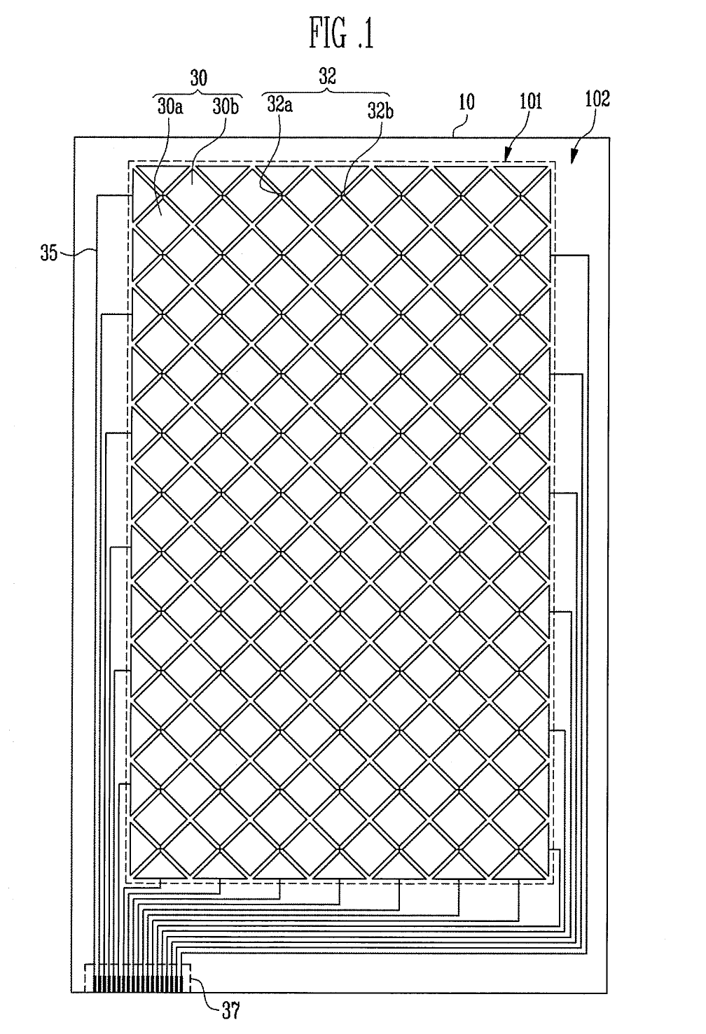

FIG. 1 is a plan view showing an example of a touch screen panel. For convenience, an example in which a plurality of touch sensing cells in diamond shape that are connected in a vertical or horizontal direction and configured to form a touch sensing pattern is shown in FIG. 1. However, it is only described as an example of the present invention, and the present invention is not limited thereto. Actually, the touch sensing pattern may be formed in various shapes, such as in another example, there is a bar shaped touch sensing cells patterned in a horizontal or vertical direction.

Referring to FIG. 1, a touch screen panel includes: a substrate 10, a plurality of touch sensing cells 30 formed on the substrate 10, connecting patterns 32 for connecting the touch sensing cells 30 in a first direction or a second direction, and outside wiring lines 35 for connecting the touch sensing cells 30 to an external driving circuit through a pad unit 37.

The substrate 10 is a base substrate, which is a base component of the touch screen panel, and may be formed using a transparent substrate material, such as a glass, polyethylene terephthalate (PET), polyimide (PI), acryl, or the like. Here, the term “transparent” refers to not only materials with 100% transparency, but also materials having a high optical transmittance.

The touch sensing cells 30 are formed on one active surface area 101 of the substrate 10. The touch sensing cells 30 may be formed of a transparent electrode material, such as indium-tin-oxide (ITO), or may be formed of a patterned metal electrode material, or the like, so as to satisfy a set or predetermined transmittance or more.

The touch sensing cells 30 as described above, in order to detect a position according to a touch input, forms a touch sensing pattern that includes a first array of sensing cells 30a connected in a first direction and a second array of sensing cells 30b connected in a second direction.

The first array of sensing cells 30a are formed to be connected in the first direction, for example, in a vertical direction, by the first connecting patterns 32a, and are connected to the outside wiring lines 35 in a column line unit, respectively.

The second array of sensing cells 30b are disposed between the first array of sensing cells 30a so as to be insulated from the first array of sensing cells 30a, and are formed to be connected in the second direction different from the first direction, for example, in a horizontal direction, by the second connecting patterns 32b and connected to the outside wiring lines 35 in a row line unit, respectively.

The first and second array of sensing cells 30a and 30b may be positioned on the same layer, and may be respectively connected in the first and second directions by the first and second connecting patterns 32a and 32b insulated from each other with an insulating layer interposed therebetween, or may be positioned on a different layer respectively with the insulating layer interposed therebetween.

The outside wiring lines 35, which are formed in a non active region on one surface of a non active area 102 of the substrate 10, connect the touch sensing cells 30 to the external drive circuit such as a touch driving circuit, through the pad unit 37.

Since the outside wiring lines 35 may be disposed in the non active area 102 positioned at the periphery of the touch screen panel other than the active area 101 displaying an image, the selection of suitable materials is large. The outside wiring lines 35 may be formed of an opaque material, such as, molybdenum (Mo), silver (Ag), titanium (Ti), copper (Cu), aluminum (Al), titanium/aluminum (Ti/Al), molybdenum/aluminum/molybdenum (Mo/Al/Mo), or the like, in addition to those suitable for an electrode material for forming the touch sensing cells 30. In addition, the limitation on thickness, width, or the like, on the outside wiring lines 35 is relatively less.

The touch screen panel as described above is an example of a capacitive touch screen panel. When touched by a contact object, such as a user's hand or stylus pen, a change of capacitance according to a contact position may be transferred to a side of driving circuit from the touch sensing cells 30 via the outside wiring lines 35 and the pad unit 37.

Then, the change in the capacitance is converted into an electrical signal by X and Y input processing circuit or the like, such that the contact position is recognized.

FIG. 2 is a cross-sectional view showing a display device integrated with a touch screen panel according to an embodiment of the present invention. Here, although the example embodiment of the present invention has described that the present invention is applied to the capacitive type touch screen panel shown in FIG. 1, the present invention is not limited thereto, and a technical spirit and a configuration of the present invention may be applied to any type of touch screen panel.

Meanwhile, for convenience, in FIG. 2, some features, such as the connecting patterns illustrated in FIG. 1 for schematically showing the touch sensing patterns, are omitted. A configuration that is the same as or similar to that of FIG. 1 will be denoted by the same reference numerals and a detailed description thereof will be omitted.

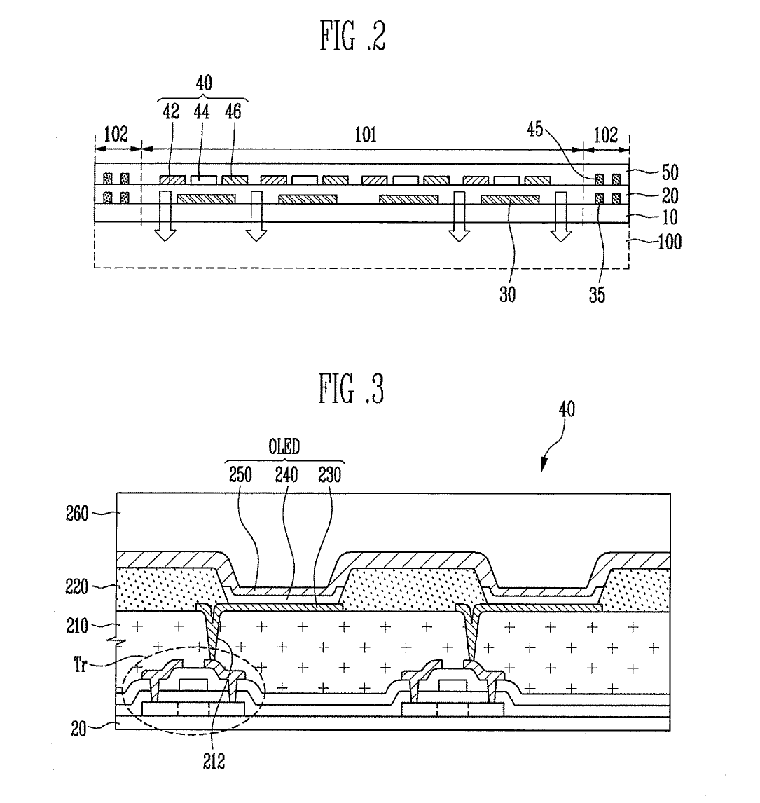

FIG. 3 is a cross-sectional view showing an example of a pixel shown in FIG. 2. FIG. 3, as described above, is an example of a pixel of an organic light emitting display device. For convenience, in FIG. 3, only a transistor which is directly connected to an organic light emitting diode is described.

First, referring to FIG. 2, the display device integrated with a touch screen panel according to one embodiment of the present invention includes: a first substrate 10, a second substrate 20 on (e.g., multilayerd on) the first substrate 10, touch sensing cells 30 and a first outside wiring lines 35 formed between the first and second substrates 10 and 20, a plurality of pixels 40 and a second outside wiring lines 45 formed on the second substrate 20, and a sealing substrate 50 formed on the pixels 40 to seal at least the pixels 40.

The first and second substrates 10 and 20 may be implemented by, for example, flexible thin film substrates. For example, the first substrate 10 and/or second substrates 20 are formed of a thin transparent film, such as a polyimide (PI) material. In one embodiment, when the first and second substrates 10 and 20 are implemented by flexible thin film substrates, there is an enhancement in which flexible characteristic is provided.

Meanwhile, when the first and second substrates 10 and 20, which are base materials of the display device integrated with the touch screen panel, are implemented by flexible thin film substrates using a process in which the first substrate 10 and/or the second substrate 20 are disposed on a hard substrate, such as a glass substrate 100 and using the hard substrate as a career substrate, the process to form the touch sensing cells 30, the pixels 40, and the like, can be proceeded easily. And then, a display device integrated with the flexible touch screen panel may be manufactured by separating the display device integrated with the touch screen panel from the glass substrate 100.

The touch sensing cells 30 are formed in an active region on the active area 101 between the first substrate 10 and the second substrate 20, and the first outside wiring lines 35 are formed in a non active region on the non active area 102 between the first substrate 10 and the second substrate 20. The touch sensing cells 30 are formed of transparent electrode material, for example, indium tin oxide (ITO), and light from the pixels 40 may be transmitted thereto.

The first outside wiring lines 35 for connecting the touch sensing cells 30 to the external touch driving circuit, or the like, are disposed in a non active region on the non active area 102 of the peripheral area of the active area 101, in which a requirement to light transmittance, or the like, is low, so that a selection of suitable material is relatively wide. For example, the first outside wiring lines 35 may be formed of an opaque material having a low electrical-resistance.

As described above, when the touch sensing cells 30, the first outside wiring lines 35, and the like, are inserted between the first substrate 10 and the second substrate 20, with a pattern formed of different materials, there is an effect of improving an adhesive force between the first substrate 10 and the second substrate 20.

That is, the touch sensing cells 30 and the first outside wiring lines 35 serve to provide a basic function for detecting the touch location, and may serve as an intermediate interfacial layer to improve the adhesion force between the first and second substrates 10 and 20 that are implemented by flexible thin film substrates.

The pixels 40 are formed on the active area 101 on the second substrate 20, and the second outside wiring lines 45, such as a power line or signal line for detecting the pixels 40, are formed on the non active area 102 on the second substrate 20.

Each of the pixels 40, for example, may include a red sub-pixel 42, a green sub-pixel 44, and a blue sub-pixel 46. The pixels 40 as described above, for example, may be implemented of the pixels of an organic light emitting display device including the organic light emitting diode (OLED) as shown in FIG. 3.

Referring to FIG. 3, where a configuration of the pixel 40 is schematically shown, the pixel 40 includes the organic light emitting diode (OLED) and a transistor Tr connected thereto.

The transistor Tr is formed on the second substrate 20, and a planarization layer 210 is formed on the transistor Tr.

The planarization layer 210 may be formed of an insulation material, such as silicon nitride or silicon oxide.

On the planarization layer 210, a first pixel electrode (an anode electrode) 230 connected to the transistor Tr through the contact hole 212 is formed, and an organic light emitting layer 240 and a second pixel electrode (a cathode electrode) 250 is sequentially formed on the first pixel electrode 230, thereby forming an organic light emitting diode (OLED).

Meanwhile, the first pixel electrode 230 may be patterned so as to form separated pixel units, and a pixel defined layer 220 may be formed between adjacent pixels. The pixel defined layer 220 may be formed of any one of a suitable insulating material, such as acryl based organic compound, polyamide, polyimide, or the like, but is not limited thereto, and may be formed of various insulating materials.

On the second pixel electrode 250, the insulating layer 260 and/or a sealing substrate 50 shown in FIG. 2 are formed.

In other words, referring to FIG. 2, the sealing substrate 50 is formed on at least pixels 40 to protect the organic light diode (OLED) and seal the pixels. The sealing substrate 50, for example, may include a thin film substrate.

As described above, a thin film substrate is used as the sealing substrate 50 to seal the display device as a thin film. There is an enhancement of reduced thickness, thereby sufficiently provide a flexible characteristic to the display device.

In addition, according to the example embodiment of the present invention, when the pixels 40 are configured by using an organic light emitting diode OLED, which is a self light-emitting device, it provides an enhancement of thin thickness, and it is appropriate to implement the flexible display device.

Meanwhile, light from the pixels 40 are designed to be emitted in a direction in which the touch sensing cells 30 are formed, that is, in a rear direction. Therefore, a surface in which the touch sensing cells 30 are formed is set to be a screen which displays images. Accordingly, touch sensing may be sufficiently secured. According to an embodiment of the present invention as described above, a display device integrated with a touch screen panel is manufactured with the first and second substrates 10 and 20 implemented by two flexible thin film substrates, thereby making it possible to manufacture a display device integrated with a thin film flexible touch screen panel.

Specifically, the display device integrated with a touch screen panel in a simple structure may be implemented by forming the touch sensing cells 30 and the first outside wiring lines 35 between the first and second substrates 10 and 20 and then improving an adhesive force between the first and second substrates 10 and 20. Therefore, a display device integrated with a flexible touch screen panel having reduced thickness and improved flexibility may be provided.

In comparison, when a touch screen panel is separately manufactured and is attached to an external surface of the display device, the total thickness of the display device is increased and the visibility of an image may be decreased.

In addition, when the thickness of the display device is increased, it serves as a factor in which the flexibility of the display device is decreased, which is against the demand for flexible display devices.

As set forth above, a display device integrated with a touch screen panel is manufactured with the first and second substrates implemented by two flexible thin film substrates, or the like, thereby making it possible to provide the display device integrated with the flexible touch screen panel.

Specifically, the display device integrated with a touch screen panel in a simple structure is implemented by forming the touch sensing cells between the first and second substrates and then improving an adhesive force between the first and second substrates. Therefore, a display device integrated with a flexible touch screen panel having reduced thickness thereof and improved flexibility can be provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singularly or in combination with features, characteristics, and/or elements described in connection with other embodiments unless otherwise specifically indicated. Accordingly, it will be understood by those of ordinary skill in the art that various changes in form and details may be made without departing from the spirit and scope of the present invention as set forth in the following claims, and equivalents thereof.

1. A display device integrated with a touch screen panel comprising:
a first substrate;
a second substrate on the first substrate and having a first surface facing the first substrate and a second surface facing oppositely away from the first substrate;
a plurality of touch sensing cells in an active region between the first substrate and the second substrate; and
a plurality of pixels directly on an active area of the second surface of the second substrate.

2. The display device integrated with the touch screen panel according to claim 1,
wherein the first and second substrates comprise a flexible thin film substrate.

3. The display device integrated with the touch screen panel according to claim 2,
wherein the first and second substrates comprise a transparent thin film substrate.

4. The display device integrated with the touch screen panel according to claim 1,
wherein the touch sensing cells comprise a transparent electrode material.

5. The display device integrated with the touch screen panel according to claim 1,
wherein the pixels are configured to display images by emitting light in a direction towards where the touch sensing cells are formed.

6. The display device integrated with the touch screen panel according to claim 1,
wherein the pixels comprise pixels of an organic light emitting display device having an organic light emitting diode.

7. The display device integrated with the touch screen panel according to claim 1, further comprising,
a sealing substrate on the pixels.

8. The display device integrated with the touch screen panel according to claim 7,
wherein the sealing substrate comprises a thin film substrate.

9. The display device integrated with the touch screen panel according to claim 1, further comprising:
outside wiring lines in a non active region between the first substrate and the second substrates.

10. The display device integrated with the touch screen panel according to claim 9,
wherein the outside wiring lines comprise an opaque metal.
